(19) United States
(12) Patent Application Publication
(10) Pub. No.: US 2003/0123111 A1
(43) Pub. Date: Jul. 3, 2003

(54) Image output system, image processing apparatus and recording medium

(76) Inventor: Jun Minakuti, Sakai-shi (JP)

Correspondence Address: SIDLEY AUSTIN BROWN & WOOD LLP, 717 NORTH HARWOOD, SUITE 3400, DALLAS, TX, 75201, US

(21) Appl. No.: 10/322,827

(22) Filed: Dec. 18, 2002

(30) Foreign Application Priority Data
Dec. 20, 2001 (JP) P2001-387501

(51) Int. Cl. G03F 3/10

(52) U.S. Cl. 358/527

(57) ABSTRACT

An image output system has a digital camera, a personal computer, and a monitor. The personal computer generates a transform tone characteristic in which a tone characteristic peculiar to the monitor is considered on the basis of an ideal tone characteristic associated with image data generated by the digital camera. When image data is transformed on the basis of the transform tone characteristic and the resultant is displayed on the monitor, the ideal tone characteristic can be reproduced on the monitor. As a result, an image captured by the digital camera can be outputted with equivalent tone characteristics from different output devices.

This application is based on application No. 2001-387501 filed in Japan, the contents of which are hereby incorporated by reference.

### BACKGROUND OF THE INVENTION

1. Field of the Invention

The present invention relates to an image output technique having a photographing apparatus for capturing image data of a subject and an output device for outputting a visible image on the basis of image output data of the image data.

2. Description of the Background Art

In an image output system which is constructed by, for example, a digital camera, a personal computer and a monitor and photo-takes and reproduces a subject such as a person, landscape, object or the like (hereinafter, referred to as “subject such as a person or the like”), if tone transformation is performed linearly, a subjectively darkish image of low contrast is obtained and an impression which is not good is given. Consequently, in such an image output system, setting is made so as to enhance the contrast a little more than actual one in order to give a subjectively preferable impression, for example, the tone transformation characteristic of a digital camera or the tone characteristic of a silver halide film.

Such setting is necessary because of a visual sense characteristic of a human. The visual sense characteristic is considered to be varied due to a difference in observation conditions between the case of observing a subject such as a person or the like and the case of observing an image reproducing the real scene, a difference in a dynamic range between the cases and the like.

Consequently, in order to make a reproduction image reproduced equivalent to an original, the variations in the visual sense characteristic of a human have to be corrected in an image output system, and the tone characteristic has to be set differently from the linear tone characteristic. The tone characteristic can be set by a subjective evaluation experiment or the like and is an ideal one to be held in an image output system reproducing a subject such as a person or the like.

Usually, in an image output system outputting a digital picture, in order to realize the ideal tone characteristic, a predetermined tone transforming process is performed in a digital camera. In this case, tone transformation is performed on assumption of only a case of outputting an image to a specific output device among a number of output devices each for outputting a visual image (hereinafter, simply referred to as “output devices”), so that the ideal tone reproduction characteristic can be realized by the specific output device.

In the image output system, however, in the case of outputting an image from a device other than the assumed specific output device, a problem arises such that an equivalent ideal tone characteristic cannot be realized.

For example, there is a case that the tone characteristic of a monitor connected to a personal computer varies according to an operation system (OS). Specifically, in many cases, in a monitor of a personal computer of the Windows (R), the luminance characteristic is expressed as γ=2.2. In a monitor of a personal computer of the Macintosh, the luminance characteristic is expressed as γ=1.8. The characteristics are different from each other. When an image of a digital camera subjected to tone transformation on assumption of using a monitor of γ=2.2 is observed on a monitor of γ=1.8, the ideal tone characteristic is not realized.

In the case of dealing with only the two kinds of output devices, it is not impossible to realize the ideal tone characteristic by preparing two kinds of ideal tone characteristics for the two kinds of output devices in a digital camera and switching the ideal tone characteristic in accordance with setting of the user. In reality, however, a number of output devices of different luminance characteristics exist. Consequently, to deal with all of output devices, a number of ideal tone characteristics have to be prepared in the camera. It is impractical from the viewpoints of the capacity of a memory provided in the digital camera, complicated switching operation and the like.

### SUMMARY OF THE INVENTION

The present invention is directed to an image output system.

According to one aspect of the present invention, this image output system having a photographing device for capturing image data of a subject and an output device for outputting a visible image on the basis of image output data of the image data, includes: (a) a storing part for storing predetermined tone characteristic information; (b) an associating part for associating the image data captured by the photographing device and the predetermined tone characteristic information with each other to thereby generate composite image information; and (c) a generator for generating the image output data by performing tone transformation on the image data on the basis of the predetermined tone characteristic information obtained from the composite image information. Thus, images captured by the photographing device can be outputted with an equivalent tone characteristic from different output devices.

In a preferred embodiment of the present invention, in the image output system, the storing part has: (a-1) a part for storing plural pieces of different tone characteristic information. Consequently, an appropriate tone characteristic can be selected.

The present invention is also directed to an image processing apparatus for generating image output data of an output device which outputs a visible image on the basis of image data captured by a photographing device, and to a recording medium on which a program that can be read by the image processing apparatus is recorded.

Therefore, an object of the present invention is to provide an image output technique capable of outputting a visible image with an equivalent tone characteristic with respect to an image captured by the photographing device even from different output devices.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram showing the configuration of main components of an image output system 100A according to a first embodiment of the present invention;

FIG. 2 is a perspective view of a digital camera 1A;

FIG. 3 is a rear view of the digital camera 1A;

FIG. 4 is a diagram showing functional blocks of the digital camera 1A;

FIG. 5 is a conceptual diagram for describing different ideal tone characteristics;

FIG. 6 is a flowchart for describing operations of the image output system 100A;

FIG. 7 is a flowchart for describing a reading operation;

FIG. 8 is a diagram for describing setting of a transform tone characteristic;

FIG. 9 is a flowchart for describing a storing operation;

FIG. 10 is a flowchart for describing a printing operation;

FIG. 11 is a flowchart for describing a setting operation;

FIG. 12 is a diagram showing a setting dialogue displayed on a monitor 3;

FIG. 13 is a flowchart for describing a reading operation of an image output system 100B according to a second embodiment of the present invention;

FIG. 14 is a diagram showing functional blocks of a digital camera IC of an image output system 100C according to a third embodiment of the present invention;

FIG. 15 is a flowchart for describing a reading operation of the image output system 100C;

FIG. 16 is a flowchart for describing a reading operation of an image output system 100D according to a fourth embodiment of the present invention; and

FIG. 17 is a flowchart for describing a reading operation of an image output system 100E according to a fifth embodiment of the present invention.

### DESCRIPTION OF THE PREFERRED EMBODIMENTS

First Embodiment

Configuration of Main Components of Image Output System

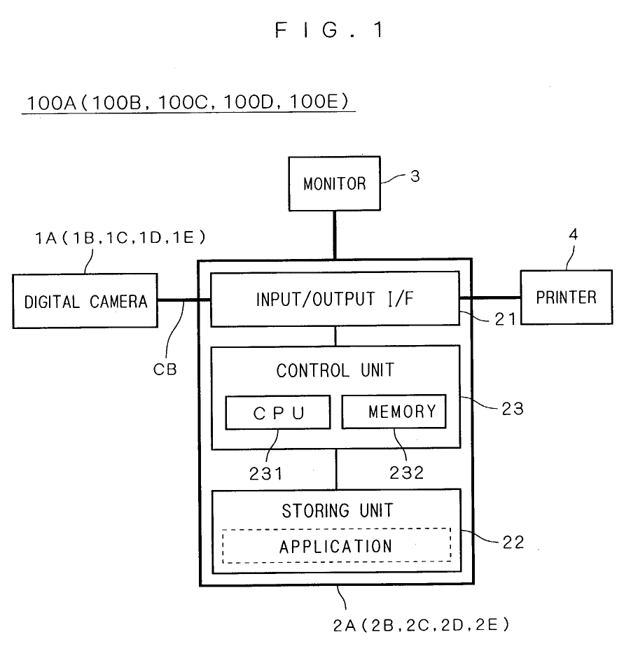

FIG. 1 is a diagram showing the configuration of main components of an image output system 100A according to a first embodiment of the present invention.

The image output system 100A has a digital camera 1A functioning as a photographing device, a personal computer 2A capable of transmitting/receiving data to/from the digital camera 1A via a communication cable CB, and a monitor 3 and a printer 4 connected to the personal computer 2A so as to transmit/receive data to/from the personal computer 2A.

The personal computer 2A functions as an image processing apparatus and has an input/output I/F 21 connected to the digital camera 1A, monitor 3 and printer 4, a storing unit 22, and a control unit 23.

The input/output I/F 21 is an interface for transmitting/receiving data to/from the digital camera 1A, monitor 3 and printer 4.

The storing unit 22 takes the form of, for example, a hard disk in which an application to be described later is stored.

The control unit 23 has a CPU 231 and a memory 232 and controls parts of the personal computer 2A. By loading an application stored in the storing unit 22 to the memory 232 of the control unit 23 and executing the application by the CPU 231, an image outputting operation (which will be described later) can be performed.

The monitor 3 takes the form of, for example, a CRT and can display an image on the basis of image output data generated by the personal computer 2A.

The printer 4 prints an image on the basis of the image output data generated by the personal computer 2A.

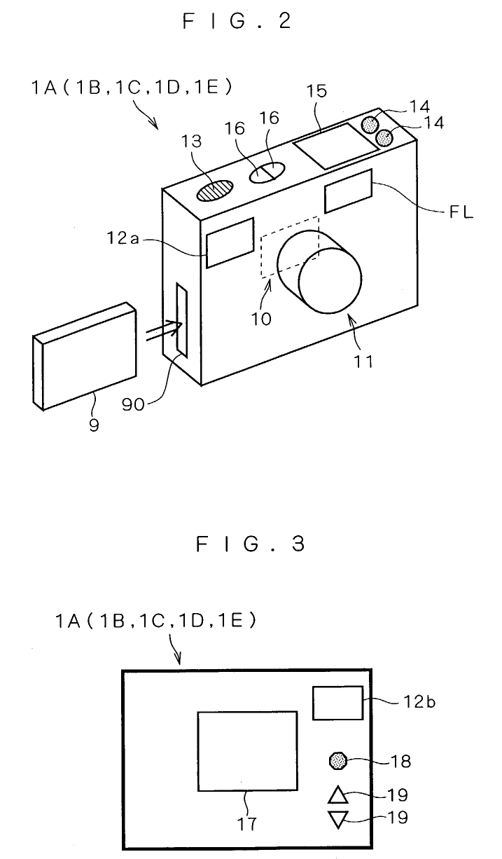

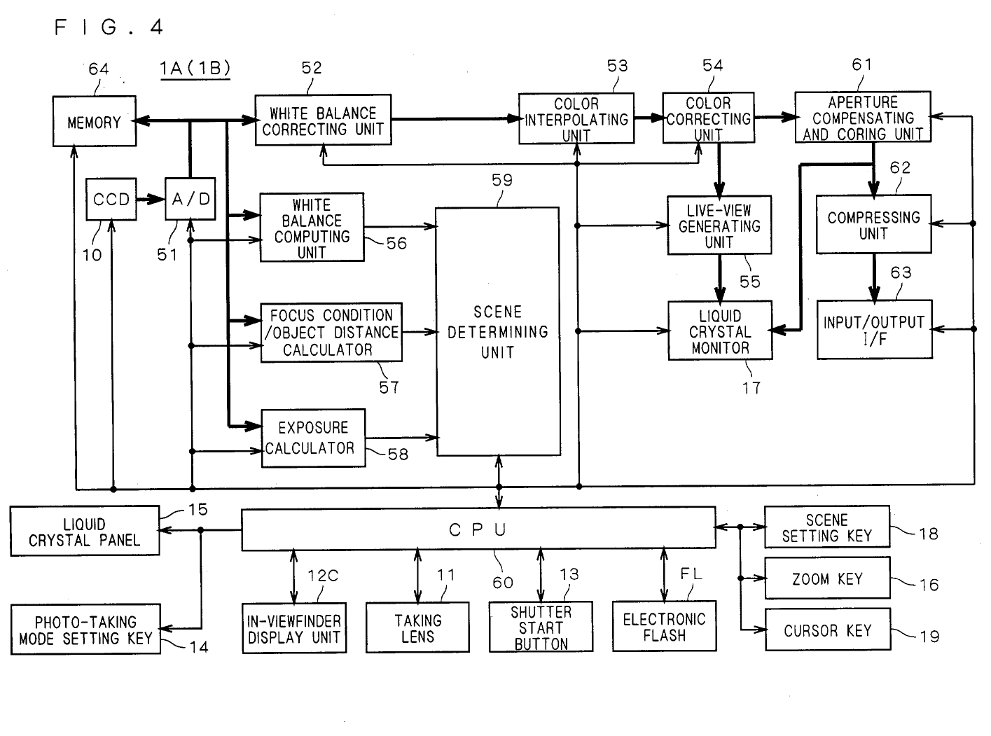

FIG. 2 is a perspective view of the digital camera 1A. FIG. 3 is a rear view of the digital camera 1A.

The digital camera 1A has, in its front face, a taking lens 11 for forming an image of a subject to a CCD (Charge Coupled Device) 10 (shown with a broken line), a viewfinder window 12a used by the user to visually recognize the subject, and an electronic flash FL. The CCD 10 converts an optical image formed by the taking lens 11 into an electric signal, thereby generating image data of the subject.

The digital camera 1A has, in its top face, a shutter start button 13 used by the user to instruct photographing, two photo-taking mode setting keys 14, a liquid crystal panel 15 for displaying an image captured, and a zoom key 16 and has, in its side face, an insertion port 90 for inserting a memory card 9 functioning as a recording medium.

By the operation of the photo-taking mode setting keys 14, the user can make setting of exposure conditions such as aperture priority and shutter speed priority and setting of switching of macro photo-taking while visually recognizing an image displayed on a liquid crystal monitor 17 (which will be described later).

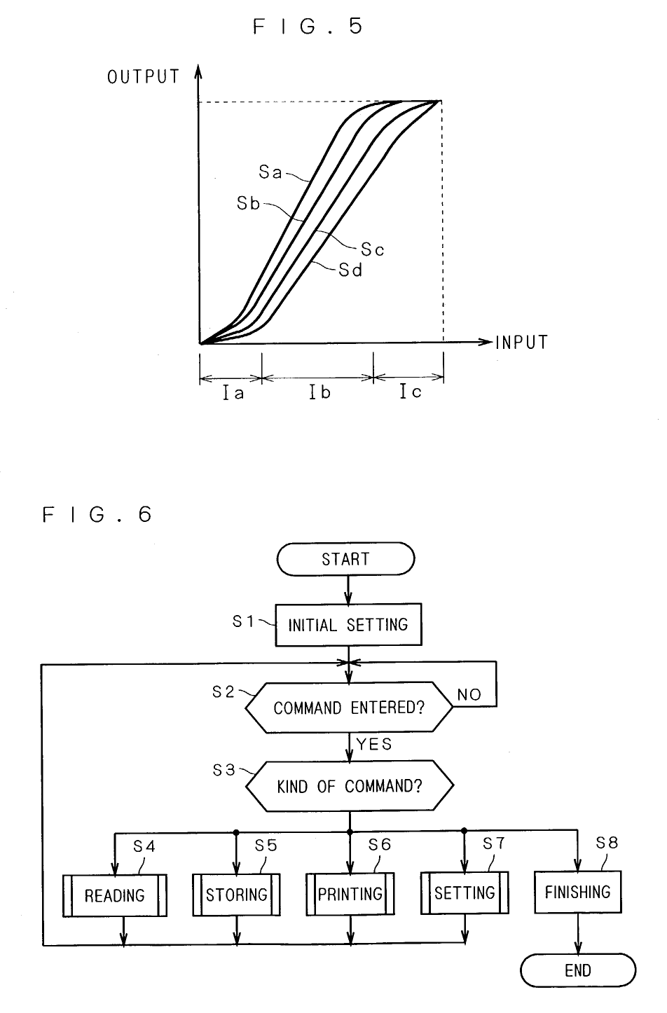

The digital camera 1A has, in its rear face, a viewfinder window 12b corresponding to the viewfinder window 12a in the front face, the liquid crystal monitor 17 for displaying image data generated by the CCD 10 and the like, a scene setting key 18, and a cursor key 19 for vertically moving a cursor displayed on the liquid crystal monitor 17. In the viewfinder window 12b, information such as photo-taking conditions is displayed by an in-viewfinder display unit 12c (see FIG. 4).

The scene setting key 18 is a part for switching a mode between an automatic scene selecting mode and a manual scene selecting mode.

The automatic scene selecting mode is a mode of automatically determining a scene to be captured and performing an optimum photo-taking control and image processing on the scene to thereby obtain a desirable image. As scenes to be automatically determined, four scenes of portrait, sports, landscape and snapshot are set. By using the magnification of capturing an image of the subject, focal length of the taking lens 11, luminance of the subject, information of a light source, and information of a dynamic subject/stationary subject, an optimum photo-taking mode can be determined. In each scene determined, by optimally performing an exposing control, electronic flash control, sharpness correction, color correction and the like, an excellent image is generated.

The manual scene selecting mode is a mode in which the user selects a scene which seems to be the best from the four scenes of portrait, sports, landscape and snapshot by operating the photo-taking mode setting keys 14, and the exposure control, electronic flash control, sharpness correction, color correction and the like are optimally performed on the basis of the selected scene.

FIG. 4 is a diagram showing functional blocks of the digital camera 1A.

The digital camera 1A can perform live-view display in which an image of the subject is displayed on the liquid crystal monitor 17 before photo-taking.

In the live-view display, an analog image signal captured by the CCD 10 is converted to a digital signal by an A/D converter 51, and the digital signal is subjected to predetermined image processes by a white balance correcting unit 52, a color interpolating unit 53 and a color correcting unit 54. The image data subjected to the image processes is passed to a live view generating unit 55 and displayed on the liquid crystal monitor 17. Consequently, the composition of the subject and the like can be grasped before capturing an image.

In the case of setting the automatic scene selecting mode in the live-view capturing, image data for a live view which is A/D converted by the A/D converter 51 is inputted to a white balance computing unit 56, a focus condition/object distance calculator 57 and an exposure calculator 58, and light source information, photo-taking distance, information of a dynamic subject/stationary subject, and information of luminance is supplied to the scene determining unit 59.

On the basis of the information and the focusing information of the taking lens 11 supplied from a CPU 60, the scene determining unit 59 determines a scene. The determined scene is transmitted to the CPU 60 and is displayed together with a live view image on the liquid crystal monitor 17.

The scene determining unit 59 also controls the aperture of the taking lens 11 on the basis of the result of determination of the scene, controls integral time of the CCD 10, and sets parameters for the color correcting unit 54 and an aperture compensating and coring unit 61 for correcting an aperture distortion and making contour compensation.

In the photo-taking, the image data generated by the CCD 10 is subjected to an image process with the set parameters, and the resultant is displayed together with the result of scene determination on the liquid crystal monitor 17. On the other hand, the image data subjected to the image processes is passed through the aperture compensating and coring unit 60 and subjected to image compression of, for example, the JPEG format by a compressing unit 62. After that, the compressed image is passed through an input/output interface (I/F) 63 and recorded on the memory card 9 inserted in the insertion port 90 or transmitted to the personal computer 2A via the communication cable CB.

In an image file, captured image data and ideal tone characteristic data associated with the image data are recorded. The ideal tone characteristic data is data used to realize ideal tone expression in the case where an image is displayed on a monitor. The captured image data in the image file is data of a linear luminance characteristic which is not subjected to y correction of an image captured by the CCD 10.

Since the ideal tone characteristic data varies according to the photo-taking modes of the portrait, sports, landscape and snapshot (see FIG. 5), four kinds of ideal tone characteristic data corresponding to the scenes are stored in a memory 64. In an image file, the ideal tone characteristic data corresponding to the scene which is set at the time of photo-taking is recorded.

FIG. 5 is a conceptual diagram for describing different ideal tone characteristics.

Four characteristic curves Sa, Sb, Sc and Sd show the input/output relations of the four scenes. When the luminance on the input side is divided into a shadow portion Ia, a middle tone portion 1b and a highlight portion Ic, the gradients of the characteristic curves in the middle tone portion 1b as a halftone range are different from each other. Consequently, four kinds of ideal tone characteristics are necessary for the four scenes.

The captured image data converted by the A/D converter 51 is temporarily stored in the memory 64. In the case where the user changes an image process, an image process can be performed again on the basis of the captured image data.

Operation of Image Output System 100A

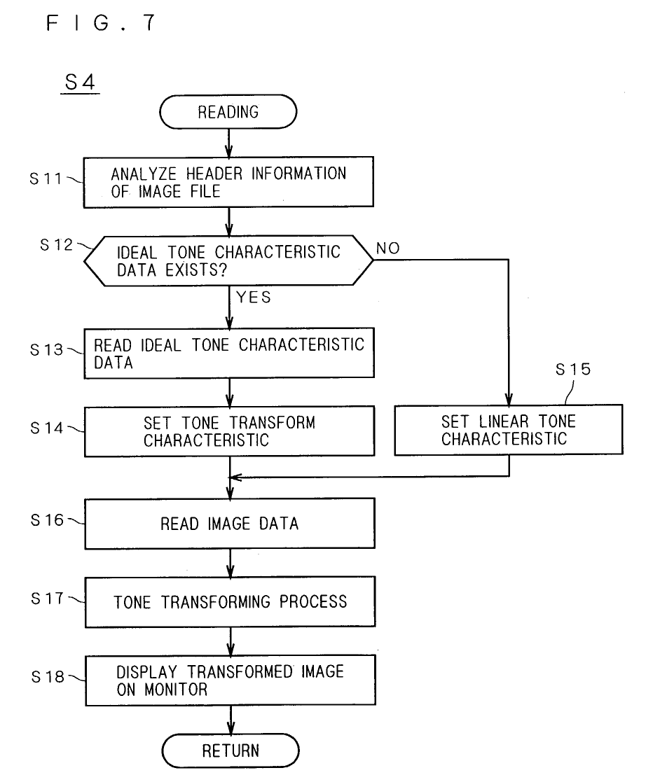

FIG. 6 is a flowchart for describing the operation of the image output system 100A. The operation is executed by starting the application stored in the storing unit 22. It is assumed that one of the four kinds of scenes is selected by the scene setting key 18 and an image of the subject is captured in the digital camera 1A before starting the application.

In step S1, various items are initially set. Default values in a setting operation in step S7 which will be described later are also set.

In step S2, whether a command is entered by the user or not is determined. Concretely, whether or not operation input is performed by a mouse or the like of the personal computer 2A on the menu screen displayed on the monitor 3 is determined. In the case where a command is entered, the program advances to step S3.

In step S3, the kind of the command entered in step S2 is determined. In this case, which one of five kinds of commands of reading, storing, printing, setting and finishing is entered is determined. According to the kind of the input command, the program advances to the corresponding one of steps S4 to S8.

In step S4, an operation of reading an image file from the digital camera 1A is performed (which will be described in detail later).

In step S5, an operation of storing an image file read in step S4 is performed (which will be described in detail later).

In step S6, an operation of printing image is performed (which will be described in detail later).

In step S7, various setting operations are performed (which will be described in detail later).

In step S8, a process of finishing an application is performed.

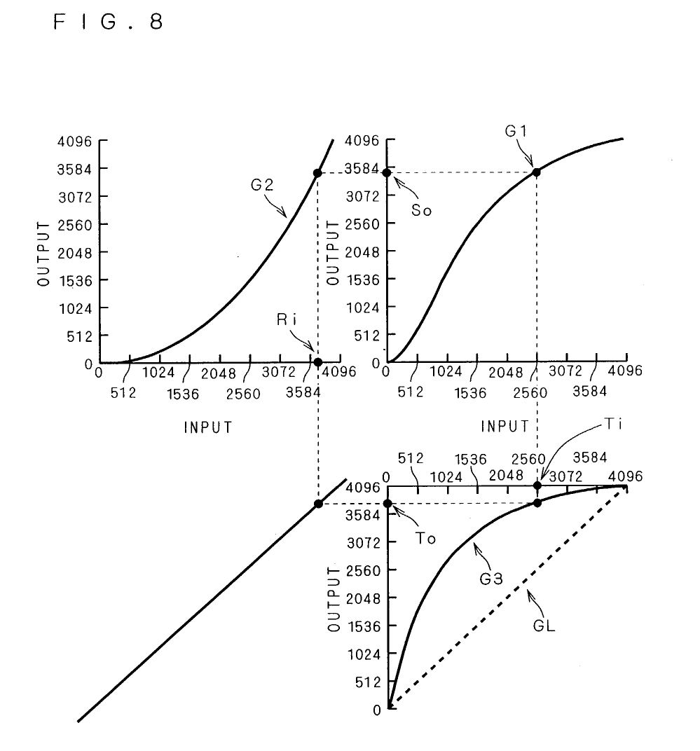

FIG. 7 shows a flowchart for describing the reading operation corresponding to step S4.

In step S11, information of the header portion of an image file read from the digital camera 1A is analyzed.

In step S12, whether there is ideal tone characteristic data or not is determined. In an image file (composite image information) sent from the digital camera 1A, information of the ideal tone characteristic is recorded together with captured image data in the header portion. By the analysis of the header portion in step S11, whether the ideal tone characteristic data exists or not is determined.

Generally, an image file of the Exif format is used in a digital camera. In the Exif format file, a space to which information peculiar to the manufacturer is provided. In the digital camera 1A of the embodiment, the ideal tone characteristic data is recorded in the space. For example, the size of the ideal tone characteristic data is recorded subsequent to a tag IDEAL_LUT indicative of an ideal tone characteristic.

If there is the ideal tone characteristic data in step S12, the program advances to step S13. If there is no ideal tone characteristic data, the program advances to step S15.

In step S13, the ideal tone characteristic data is read from the image file. The ideal tone characteristic data read is stored as a data table into the memory 232 of the control unit 23. The ideal tone characteristic data corresponds to a scene selected at the time of photo-taking.

In step S14, as a pre-process for performing the tone transforming process in step S17, a transform tone characteristic is set. The setting of the transform tone characteristic will be described later in detail.

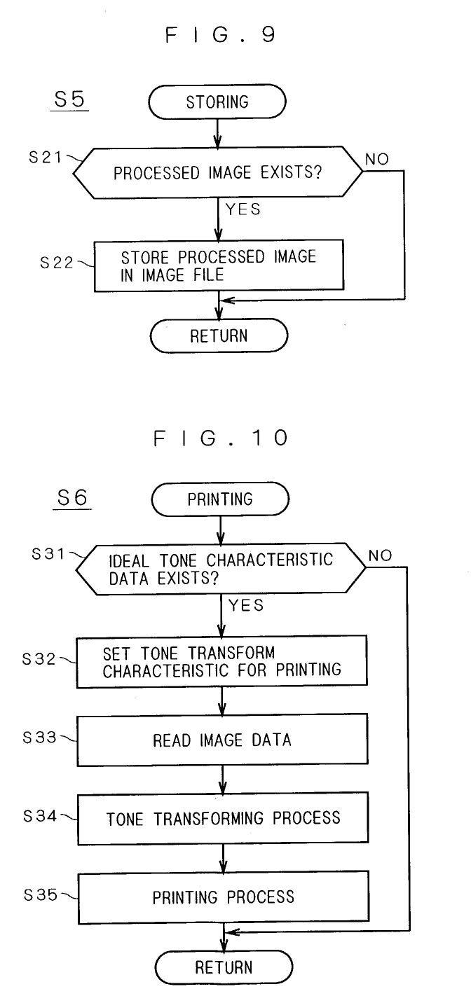

FIG. 8 is a diagram for describing setting of the transform tone characteristic.

A curve G1 is a characteristic curve indicative of the ideal tone characteristic obtained in step S13. A curve G2 is a characteristic curve indicative of the tone characteristic peculiar to an output device for outputting a visible image, concretely, the monitor 3. A curve G3 is a characteristic curve indicative of a transform tone characteristic to be obtained. A method of obtaining an output value To corresponding to an input value Ti in the characteristic curve G3 will now be described.

First, in the characteristic curve G1 indicative of the ideal tone characteristic, an output value So corresponding to the input value Ti is obtained. Next, in the characteristic curve G2 indicative of the tone characteristic peculiar to the output device, an input value Ri corresponding to the output value So is obtained. The tone characteristic peculiar to the monitor 3 as an output device is stored as a data table in the memory 232 of the control unit 23. By changing the addresses of an input and an output of the data table with each other, the input value Ri is obtained. The input value Ri is set as an output value To corresponding to the input value Ti in the characteristic curve G3. By performing such a process also on a value different from the input value Ti, the characteristic curve G3 indicative of the transform tone characteristic is obtained.

By obtaining the transform tone characteristic by multiplying the reverse characteristic of the tone characteristic peculiar to the output device and the ideal tone characteristic together, irrespective of the tone characteristic peculiar to the output device, an image of a proper luminance characteristic based on the ideal tone characteristic is outputted.

In step S15, since there is no ideal tone characteristic data in the image file, to prevent an excessive tone transforming process in step S17 from being performed, a linear tone characteristic in which an input and an output become linear as shown by a characteristic curve GL (imaginary line) in FIG. 8 is set as a transform tone characteristic.

In step S16, image data to be recorded in the image file is read. In this case, a process of decompressing image data which is compressed in the JPEG format is performed.

In step S17, a tone transforming process is performed on the image data read in step S16. In this case, a transforming process is performed on the basis of data of the transform tone characteristic which is set in step S14. The processed image data (image output data) subjected to tone transformation is temporarily stored in the memory 232 in the control unit 23.

In step S18, the image subjected to the tone transformation in step S17 is displayed on the monitor 3. In such a manner, an image in which the ideal tone characteristic shown by the characteristic curve G1 in FIG. 8 is reflected faithfully can be displayed.

FIG. 9 is a flowchart for describing a storing operation corresponding to step S5.

In step S21, whether image data already subjected to the tone transforming process exists in the memory 232 in the control unit 23 or not is determined. If there is the processed image, the program advances to step S22. If there is no processed image, the program returns to step S2.

In step S22, a dialog box for inputting a file name and the like is displayed on the monitor 3, and the processed image data is stored in, for example, an image file in the storing unit 22 on the basis of the inputted information.

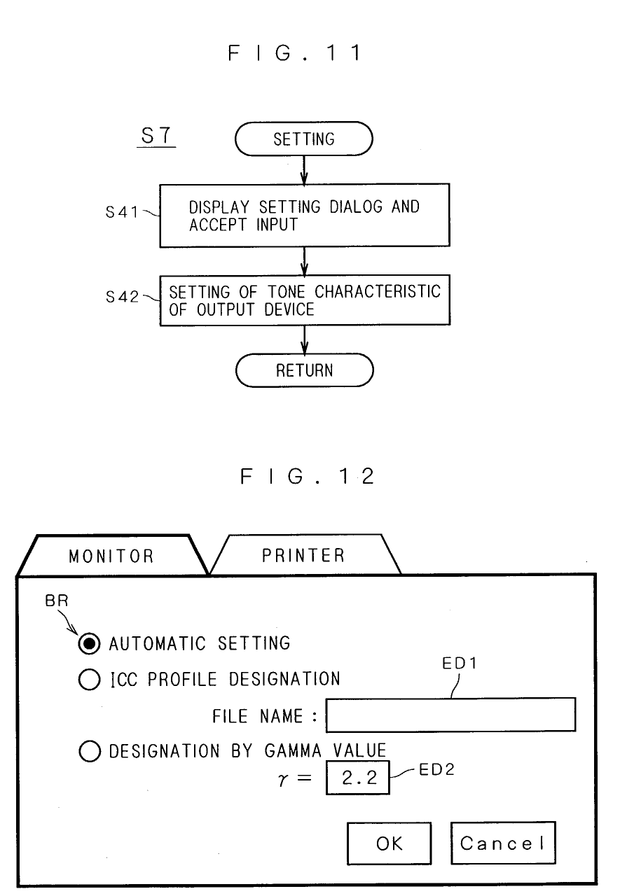

FIG. 10 is a flowchart for describing the printing process corresponding to step S6.

In step S31, whether there is the ideal tone characteristic data or not is determined. In this case, since the ideal tone characteristic data is stored in the memory 232 in the control unit 23 in step S13, whether there is the ideal tone characteristic data in the memory 232 or not is determined. If YES, the program advances to step S32. If NO, the program returns to step S2.

In step S32, a transform tone characteristic for printing is set. As a process of calculating the transform tone characteristic, a process similar to that in step S14 is performed. However, the characteristic curve G2 of FIG. 8 indicative of the tone characteristic peculiar to the output device is a curve reflecting the tone characteristic peculiar to the printer 4, not the monitor 3.

In step S33, in a manner similar to step S16, image data is read from an original image file.

In step S34, in a manner similar to step S17, a tone transforming process is performed on image data on the basis of the data of the transform tone characteristic which is set in step S32. The processed image data (image output data) subjected to tone transformation is temporarily stored in the memory 232 in the control unit 23.

In step S35, the image data which is tone transformed in step S34 is transmitted to the printer 4 and a printing process is performed. In this case as well, an image in which the ideal tone characteristic indicated by the characteristic curve GI of FIG. 8 is faithfully reflected can be printed.

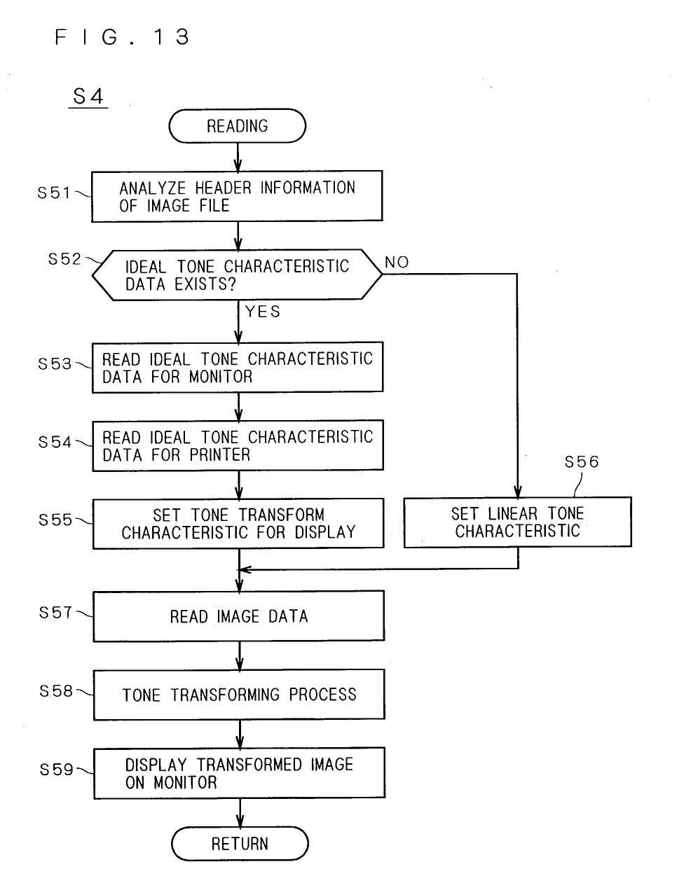

FIG. 11 is a flowchart for describing the setting operation corresponding to step S7.

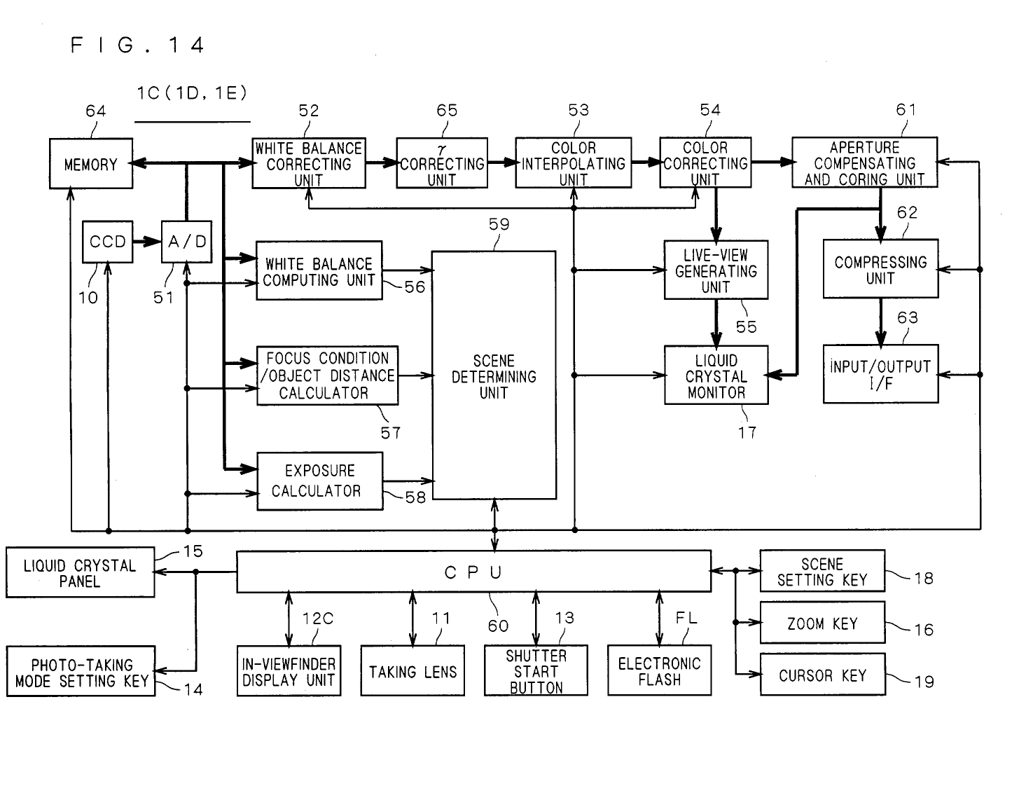

In step S41, the setting dialog box shown in FIG. 12 is displayed on the monitor 3 and a setting input by the user is accepted.

In step S42, on the basis of the information which is set in step S41, the tone characteristic peculiar to the output device shown by the characteristic curve G2 in FIG. 8 is set with respect to each of the monitor 3 and the printer 4 as output devices connected to the personal computer 2A. The set tone characteristic is stored as a data table in the memory 232 in the control unit 23.

The details of the setting input to the setting dialog shown in FIG. 12 will now be described.

When “automatic setting” is selected by a radio button BR in the setting dialogue box, by using information of color matching in the operation system (OS) of the personal computer 2A, the tone characteristic of the output device is set.

Generally, in the OS, as information used for color matching, information of the monitor and the printer connected to the personal computer is set. The information can be obtained by using an API (Application Programming Interface) specified by the OS. To be specific, by the information obtained from the API, an ICC profile used for the tone characteristic peculiar to the output device connected to the personal computer 2A can be obtained.

In the case where “ICC profile designation” is set by the radio button BR in the setting dialog box, on the basis of an ICC profile of a file name designated in an edit box ED1, the tone characteristic peculiar to the output device can be obtained.

In the case where “designation by a gamma value” is set by the radio button BR in the setting dialog box, the tone characteristic peculiar to the output device can be set on the basis of a γ value designated in an edit box ED2. In this case, a data table corresponding to the set γ value is generated and stored in the memory 232. The setting by the γ value is suitable for an output device whose tone characteristic can be easily expressed by a γ curve like the tone characteristic of a monitor.

When the size (bit length corresponding to resolution of tone) of the data table of the tone characteristic obtained on the basis of the data table of the ICC profile is different from that of a data table which can be used in the application, interpolation of data or thinning of data is performed to adjust the size so as to be used in the application.

By the operation of the image output system 100A, an image is outputted from the output device on the basis of ideal tone characteristic data associated with image data obtained by the digital camera 1A. Consequently, an image can be outputted with an equivalent tone characteristic also by a different output device.

Second Embodiment

An image output system 100B of a second embodiment of the present invention has a configuration similar to that of the image output system 100A of the first embodiment except for the configuration of a digital camera and a personal computer.

The digital camera 1A stores the four kinds of ideal tone characteristic data which is shared by the monitor and the printer in the memory 64. On the other hand, in the second embodiment, a digital camera 1B of the image output system 100B is different from the above with respect to the point that four kinds of ideal tone characteristic data for each of output devices, that is, the monitor and the printer are stored in the memory 64. The monitor is a light emitting device and performs reproduction based on additive mixture of colors. In contrast, the printer is a device for giving color materials onto a sheet of paper and performs reproduction based on subtractive mixture of colors. Since the devices have different conditions such as principle of reproduction and the dynamic range, it is preferable to make their ideal tone characteristics different from each other. Therefore, in the digital camera 1B of the second embodiment, the ideal tone characteristic data for each of output devices, that is, the monitor and the printer is stored in the memory 64.

In an image file generated at the time of photo-taking, two ideal tone characteristic data for the monitor and the printer corresponding to scenes at the time of photo-taking are recorded in association with the captured image data.

In a personal computer 2B of the image output system 100B, an application different from the application of the personal computer 2A of the first embodiment is stored in the storing unit 22. In the application, the operations of the image output system 100B which will be described later are executed.

The operations of the image output system 100B are similar to those of the flowchart of FIG. 6 except for the reading operation in step S4 and the printing operation in step S6.

FIG. 13 is a flowchart for describing the reading operation of the image output system 100B.

In steps S51 and S52, operations similar to those in steps S11 and S12 in FIG. 7 are performed.

In step S53, the ideal tone characteristic data for monitor is read out from the image file. The read ideal tone characteristic data for monitor is stored as a data table into the memory 232 of the control unit 23.

In step S54, the ideal tone characteristic data for printer is read out from the image file. The read ideal tone characteristic data for printer is stored as a data table into the memory 232 of the control unit 23.

In step S55, in a manner similar to step S14 in FIG. 7, a transform tone characteristic for display is set as a pre-process for performing the tone transforming process in step S58. In this case, the transform tone characteristic for display is obtained on the basis of the ideal tone characteristic data for monitor read in step S53.

In steps S56 to S59, operations similar to those in steps S15 to S18 in FIG. 7 are performed.

On the other hand, the flowchart of the printing operation is similar to that of FIG. 10 shown in the first embodiment. The printing operation of the image output system 100B is different from that of the first embodiment with respect to the point that, in the operation corresponding to step S32 in FIG. 10, the transform tone characteristic is set on the basis of, not the ideal tone characteristic data for monitor, but the ideal tone characteristic data for printer.

The operation of the image output system 100B produces an effect similar to that of the first embodiment. Further, since the image data is associated with the ideal tone characteristic data for monitor and the ideal tone characteristic data for printer, an image can be outputted with the optimum tone characteristic for each of the monitor and the printer.

Third Embodiment

An image output system 100C of a third embodiment of the present invention has a configuration similar to that of the image output system 100A of the first embodiment except for the configurations of the digital camera and the personal computer.

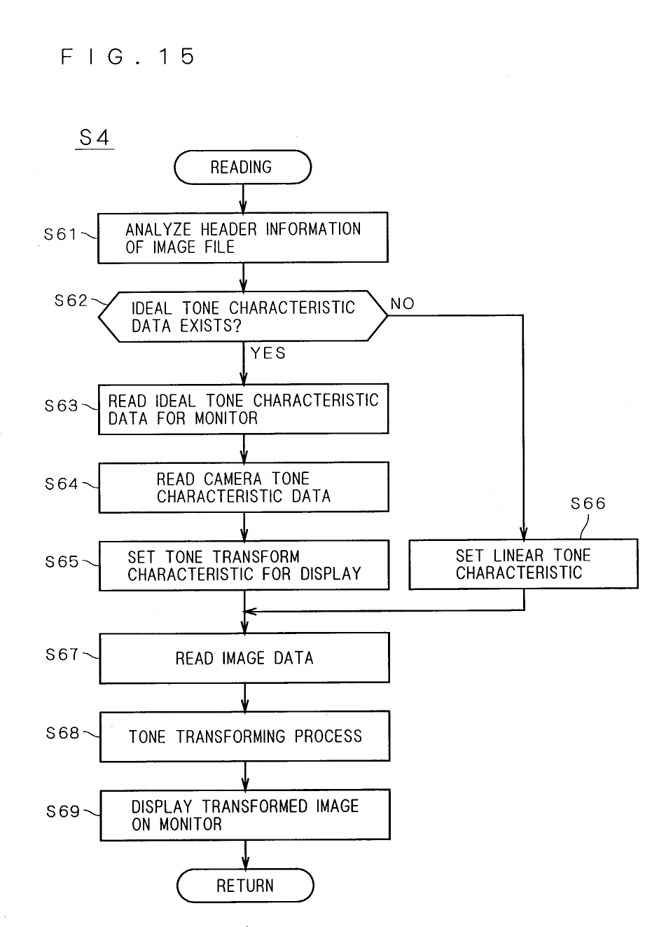

FIG. 14 is a diagram showing functional blocks of a digital camera IC of the image output system 100C.

The digital camera 1C is obtained by adding a γ correcting unit 65 to the digital camera 1A of the first embodiment.

The γ correcting unit 65 is a part for performing γ correction, that is, tone transformation based on tone characteristic data having a γ curve on the image data captured by the CCD 10. By the operation, image data subjected to predetermined tone transformation can be recorded in an image file.

The tone characteristic data used for the tone transformation by the y correcting unit 65 is stored as camera tone characteristic data into the memory 64 together with four kinds of the ideal tone characteristic data for monitor. In the image file generated at the time of photo-taking, the ideal tone characteristic data for monitor and the camera tone characteristic data corresponding to a scene at the time of photo-taking are recorded in association with captured image data.

In a personal computer 2C of the image output system 100C, an application different from the application of the personal computer 2A of the first embodiment is stored in the storing unit 22. In the application, operations of the image output system 100C which will be described next are executed.

The operation of the image output system 100C is similar to that of the flowchart of FIG. 6 except for the reading operation in step S4 and the printing operation in step S6.

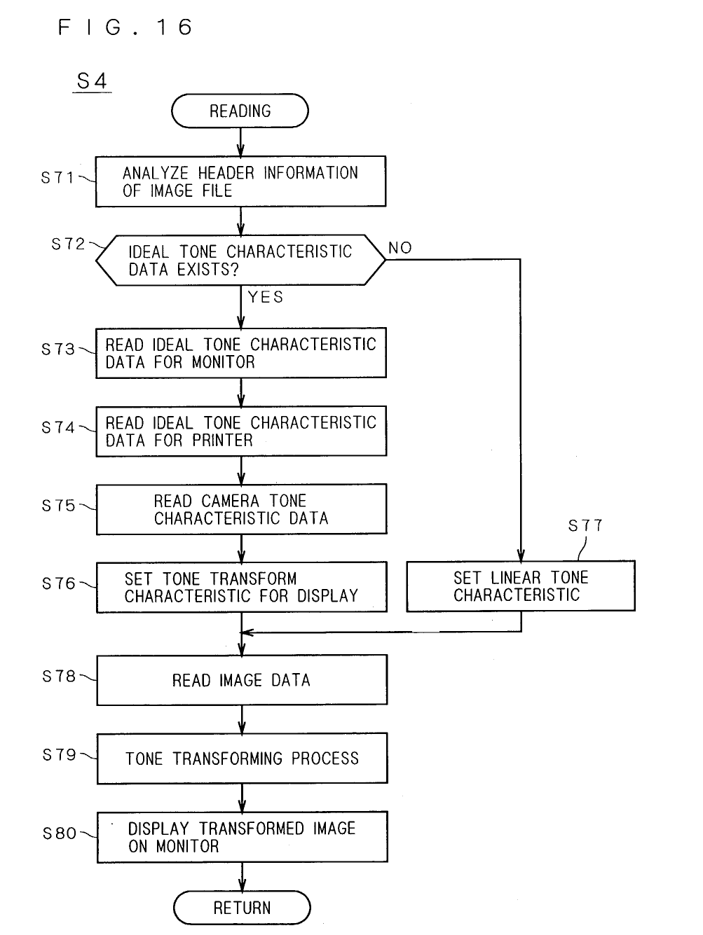

FIG. 15 is a flowchart for describing the reading operation of the image output system 100C.

In steps S61 and S62, operations similar to those in steps S11 and S12 in FIG. 7 are performed.

In step S63, the ideal tone characteristic data for monitor is read out from the image file. The read ideal tone characteristic data for monitor is stored as a data table into the memory 232 of the control unit 23.

In step S64, the camera tone characteristic data is read out from the image file. The read camera tone characteristic data is stored as a data table into the memory 232 of the control unit 23.

In step S65, in a manner similar to step S14 in FIG. 7, a transform tone characteristic for display is set as a pre-process for performing the tone transforming process in step S68.

In FIG. 8, by changing the characteristic curve G2 from the tone characteristic of only the output device to a composite tone characteristic obtained by multiplying the camera tone characteristic read in step S64 and the tone characteristic peculiar to the output device (monitor 3) together, a transform tone characteristic for display is obtained.

In steps S66 to S69, operations similar to those in steps S15 to S18 in FIG. 7 are performed.

On the other hand, the flowchart of the printing operation is similar to that of FIG. 10 described in the first embodiment. The printing operation of the image output system 100C is different from that of the first embodiment with respect to the point that, in the operation corresponding to step S32 in FIG. 10, in a manner similar to step S65, the transform tone characteristic for printing is set on the basis of the composite tone characteristic obtained by multiplying the camera tone characteristic and the tone characteristic peculiar to the printer 4 together.

The operation of the image output system 100C produces an effect similar to that of the first embodiment. Further, since the digital camera 1C can generate captured image data subjected to tone transformation (γ correction), although the ideal tone characteristic cannot be reproduced, an image at a level which can be appreciated as an image can be outputted to a monitor or the like also in a personal computer which does not have the application.

Fourth Embodiment

An image output system 100D of a fourth embodiment of the present invention has a configuration similar to that of the image output system 100C of the third embodiment except for the configuration of the digital camera and the personal computer.

In the digital camera 1C, four kinds of ideal tone characteristic data and the camera tone characteristic data which are commonly used by the monitor and printer are stored in the memory 64. In contrast, in the fourth embodiment, in the digital camera ID of the image output system 100D, the four kinds of ideal tone characteristic data for each of output devices, that is, the monitor and the printer and the camera tone characteristic data are stored in the memory 64.

In an image file generated at the time of photo-taking, two kinds of ideal tone characteristic data for monitor and printer corresponding to a scene at the time of photo-taking and camera tone characteristic data are recorded so as to be associated with captured image data.

In a personal computer 2D of the image output system 100D, an application different from the application of the personal computer 2C of the third embodiment is stored in the storing unit 22. In the application, operations of the image output system 100D which will be described next are executed.

The operation of the image output system 100D is similar to that of the flowchart of FIG. 6 except for the reading operation in step S4 and the printing operation in step S6.

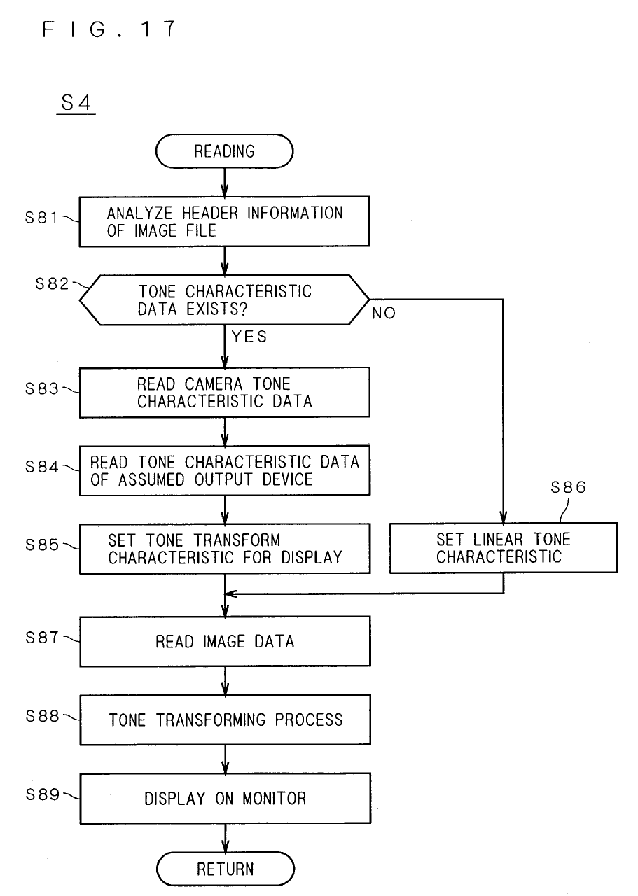

FIG. 16 is a flowchart for describing the reading operation of the image output system 100D.

In steps S71 to S73, operations similar to those in steps S61 to S63 in FIG. 15 are performed.

In step S74, the ideal tone characteristic data for printer is read out from the image file. The read ideal tone characteristic data for printer is stored as a data table into the memory 232 of the control unit 23.

In steps S75 to S80, operations similar to those in steps S64 to S69 in FIG. 15 are performed.

On the other hand, the flowchart of the printing operation is similar to that of FIG. 10 described in the first embodiment. The printing operation of the image output system 100D is different from that of the first embodiment with respect to the point that, in the operation corresponding to step S32 in FIG. 10, the transform tone characteristic for printing is set on the basis of the ideal tone characteristic for printer and the composite tone characteristic obtained by multiplying the camera tone characteristic and the tone characteristic peculiar to the printer 4 together.

The operation of the image output system 100D produces an effect similar to that of the third embodiment. Further, since the ideal tone characteristic data for monitor and that for printer are associated with the image data, in a manner similar to the second embodiment, an image can be outputted with an optimum tone characteristic for each of the monitor and printer.

Fifth Embodiment

An image output system 100E of a fifth embodiment of the present invention has a configuration similar to that of the image output system 100C of the third embodiment except for the configuration of the digital camera and the personal computer.

The digital camera 1C stores the ideal tone characteristic data and the camera tone characteristic data in the memory 64. In contrast, a digital camera 1E of the image output system 100E stores tone characteristic data of an assumed output device (e.g., monitor) and camera characteristic data.

In an image file generated at the time of photo-taking, the tone characteristic data of an assumed output device and the camera tone characteristic data are recorded in association with captured image data.

In a personal computer 2E of the image output system 100E, an application different from the application of the personal computer 2C of the third embodiment is stored in the storing unit 22. In the application, operations of the image output system 100E which will be described later are executed.

The operations of the image output system 100E are similar to those of the flowchart of FIG. 6 except for the reading operation in step S4 and the printing operation in step S6.

FIG. 17 is a flowchart for describing the reading operation of the image output system 100E.

In steps S81 and S82, operations similar to those in steps S61 and S62 in FIG. 15 are performed.

In step S83, the camera tone characteristic data is read out from the image file. The read camera tone characteristic data is stored as a data table into the memory 232 of the control unit 23.

In step S84, the tone characteristic data of the assumed output device is read out from the image file. The read tone characteristic data of the assumed output device is stored as a data table into the memory 232 of the control unit 23.

In steps S85 to S89, operations similar to those in steps S65 to S69 in FIG. 15 are performed.

On the other hand, the flowchart of the printing operation is similar to that of FIG. 10 described in the first embodiment. The printing operation of the image output system 100E is different from that of the first embodiment with respect to the point that, in the operation corresponding to step S32 in FIG. 10, the transform tone characteristic for printing is set on the basis of the tone characteristic of the assumed output device and the tone characteristic peculiar to the printer 4.

By the operations of the image output system 100E, based on the tone characteristic data of the assumed output device associated with the image data obtained by the digital camera 1E, an image is outputted from the output device. Consequently, an image can be outputted with an equivalent tone characteristic from a different output device.

Further, in the case where the tone characteristic of the assumed output device can be expressed by a single numerical value (e.g., a γ value) like a monitor, there is an advantage that an amount of information recorded on an image file decreases and the file size can be reduced.

Modifications

In the above described second and fourth embodiments, it is not indispensable to record two kinds of ideal tone characteristic data for a monitor and a printer into an image file. For example, at the time of capturing an image, it is also possible to select one of the two ideal tone characteristic data by the user and record only the selected one to an image file.

Although an image file is transferred from a digital camera to a personal computer via a cable in each of the above described embodiments, it is also possible to read an image file by a personal computer via a memory card in which the image file is stored by a digital camera.

While the invention has been shown and described in detail, the foregoing description is in all aspects illustrative and not restrictive. It is therefore understood that numerous modifications and variations can be devised without departing from the scope of the invention.

What is claimed is:

1. An image output system having a photographing device for capturing image data of a subject and an output device for outputting a visible image on the basis of image output data of said image data, the image output system comprising:
(a) a storing part for storing predetermined tone characteristic information;
(b) an associating part for associating said image data captured by said photographing device and said predetermined tone characteristic information with each other to thereby generate composite image information; and
(c) a generator for generating said image output data by performing tone transformation on said image data on the basis of said predetermined tone characteristic information obtained from said composite image information.

2. The image output system according to claim 1, wherein said storing part has:
(a-1) a part for storing plural pieces of different tone characteristic information.

3. The image output system according to claim 2, wherein
said photographing device includes:
a selector for selecting one of a plurality of photo-taking modes, and
each of said plural pieces of tone characteristic information is information which is set in correspondence with each of said plurality of photo-taking modes.

4. The image output system according to claim 2, wherein
each of said plural pieces of tone characteristic information is information which is set in correspondence with each of a plurality of output devices.

5. The image output system according to claim 2, wherein
said plural pieces of tone characteristic information have different gradients in a half tone range of characteristic curves indicative of tone characteristics.

6. The image output system according to claim 1, wherein
said predetermined tone characteristic information is recorded in a header portion of said composite image information.

7. The image output system according to claim 1, wherein
said generator has:
(c-1) a part for storing peculiar tone characteristic information with respect to said output device;
(c-2) a part for obtaining a transform tone characteristic on the basis of said peculiar tone characteristic information and said predetermined tone characteristic information; and
(c-3) a part for generating said image output data by performing tone transformation on said image data on the basis of said transform tone characteristic.

8. An image processing apparatus for generating image output data for an output device which outputs a visible image on the basis of image data captured by a photographing device having a storing part for storing predetermined tone characteristic information and an associating part for associating image data of a subject captured by photographing part with said predetermined tone characteristic information, thereby generating composite image information, the image processing apparatus comprising:
(a) an obtaining part for obtaining said predetermined tone characteristic information from said composite image information; and
(b) a generator for generating said image output data by performing tone transformation on said image data on the basis of said predetermined tone characteristic information obtained by said obtaining part.

9. The image processing apparatus according to claim 8, wherein
said generator includes:
(b-1) a part for storing peculiar tone characteristic information with respect to said output device;
(b-2) a part for obtaining a transform tone characteristic on the basis of said peculiar tone characteristic information and said predetermined tone characteristic information; and
(b-3) a part for generating said image output data by performing tone transformation on said image data on the basis of said transform tone characteristic.

10. A recording medium in which a program is recorded, which can be read by an image processing apparatus for generating image output data for an output device which outputs a visible image on the basis of image data captured by a photographing device having a storing part for storing predetermined tone characteristic information and an associating part for associating image data of a subject captured by a photographing part with said predetermined tone characteristic information, thereby generating composite image information, wherein
when said program is installed into said image processing apparatus, said program allows said image processing apparatus to execute the steps of:
(a) obtaining said predetermined tone characteristic information from said composite image information; and
(b) generating said image output data by performing tone transformation on said image data on the basis of said predetermined tone characteristic information obtained in said step (a).

11. The recording medium according to claim 10, wherein
said step (b) includes the sub-steps of:
(b-1) storing peculiar tone characteristic information with respect to said output device;
(b-2) obtaining a transform tone characteristic on the basis of said peculiar tone characteristic information and said predetermined tone characteristic information; and
(b-3) generating said image output data by performing tone transformation on said image data on the basis of said transform tone characteristic.
